(19) United States
(12) Patent Application Publication
(10) Pub. No.: US 2010/0159683 A1
(43) Pub. Date: Jun. 24, 2010

(54) Method for Fabricating Semiconductor Device Having Recess Channel

(75) Inventors: Jin Yul Lee, Icheon-si (KR); Bong Ho Choi, Seoul (KR); Kwang Kee Chae, Icheon-si (KR); Dong Seok Kim, Seoul (KR); Jae Seon Yu, Icheon-si (KR); Hyung Hwan Kim, Icheon-si (KR); Jae Kyun Lee, Icheon-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Gyeonggi-do (KR)

(21) Appl. No.: 12/494,055

(22) Filed: Jun. 29, 2009

(30) Foreign Application Priority Data
Dec. 23, 2008 (KR) 10-2008-0132694

(51) Int. Cl. H01L 21/28; H01L 21/306

(52) U.S. Cl. 438/585; 438/700; 257/E21.158; 257/E21.215

(57) ABSTRACT

A method for fabricating a semiconductor device having a recess channel includes forming an isolation layer that delimits an active region over a semiconductor substrate; exposing a region to be formed with a bulb recess trench over the semiconductor substrate; forming an upper trench by etching the exposed portion of the semiconductor substrate; forming, on a side wall of the upper trench, a silicon nitride barrier layer that exposes a bottom face of the upper trench but blocks a side wall of the upper trench; forming a lower trench of a bulb type by etching the exposed bottom face of the upper trench using the etch barrier layer as an etch mask, to form the bulb recess trench including the upper trench and the lower trench; forming a fin-structured bottom protrusion part including an upper face and a side face by etching the isolation layer so that the isolation layer has a surface lower than the bottom face of the lower trench; and forming a gate stack overlapped with the bulb recess trench and the bottom protrusion part.

### CROSS-REFERENCE TO RELATED APPLICATION

Priority to Korean patent application No. 10-2008-0132694, filed on Dec. 23, 2008, the entire disclosure of which is incorporated by reference, is claimed.

### BACKGROUND OF THE INVENTION

1. Field of the Invention

The invention relates to a method for fabricating a semiconductor device having a recess channel.

2. Brief Description of Related Technology

As design rules of semiconductor devices have been rapidly reduced with increases in degree of integration, it has become increasingly difficult to ensure stable operation of transistors. Particularly, as the design rule of a semiconductor device is reduced to 50 nm technology and below, various device properties represent a limitation with reduction in a cell area. As the cell area is reduced, the size of a transistor is also reduced, which causes difficulty in ensuring of a margin of cell threshold voltage (Vt) and refresh properties. Accordingly, methods for ensuring greater length of an effective channel without an increase in the design rule have been studied. Among such methods, there has been suggested a fin-type field effect transistor (FinFET), in which a transistor including a recess channel and a fin-shaped active region are coupled. In this Fin FET, the fin-shaped active region formed of a trapezoidal protrusion is coupled to a bottom face of the transistor including the recess channel and the channel length is thus lengthened.

With the introduction of this FinFET, a margin of the cell threshold voltage has been improved and a stable threshold voltage window of the cell transistor has been ensured. ON and OFF characteristics of the cell threshold voltage have been confirmed to result from the profile of the FinFET. Particularly, the OFF characteristic of the cell transistor can be understood to be improved by expansion of a gate control region with respect to a side wall and a corner portion in the fin-shaped active region. Also, such a FinFET device has an increased current path as compared to the recess channel and thus provides quite an advantage in an on-current state.

However, the refresh property has not yet reached the required level in spite of such improvement in the threshold voltage margin of the cell transistor. Lowering in the refresh property of the cell transistor is considered to be caused by the profile of the FinFET together with deterioration in the short channel margin resulting from reduction in the device size. In the profile of the FinFET, a critical dimension thereof is decreased with respect to the bottom face of the recess channel, by the fin-shaped active region formed of a trapezoidal protrusion. Accordingly, it is difficult to ensure a suitable threshold voltage required for operation of the cell transistor.

Thus, in the profile of the FinFET, an increased dose of cell channel ions is required to meet a target voltage of the cell threshold voltage, which functions is a main cause of a deterioration in the refresh property. Consequently, it is necessary to provide a method capable of improving the cell current properties by simultaneously realizing the advantages of the FinFET structure and the transistor structure, including a recess channel, and thus ensuring the margin of the cell threshold voltage while improving the refresh property.

### SUMMARY OF THE INVENTION

In one embodiment, a method for fabricating a semiconductor device having a recess channel includes forming an isolation layer that delimits an active region over a semiconductor substrate; exposing a region to be formed with a bulb recess trench over the semiconductor substrate; forming an upper trench by etching the exposed portion of the semiconductor substrate; forming, on a side wall of the upper trench, a silicon nitride barrier layer that exposes a bottom face of the upper trench but blocks a side wall of the upper trench; forming a lower trench of a bulb type by etching the exposed bottom face of the upper trench using the silicon nitride barrier layer as an etch mask, to form the bulb recess trench including the upper trench and the lower trench; forming a fin-structured bottom protrusion part including an upper face and a side face by etching the isolation layer so that the isolation layer has a surface lower than the bottom face of the lower trench; and forming a gate stack overlapped with the bulb recess trench and the bottom protrusion part.

Forming the upper trench preferably comprises blocking the exposed region of the semiconductor substrate except for a region to be formed with the bulb recess trench in the active region by forming a screen oxide layer pattern and an amorphous carbon layer pattern over the semiconductor substrate; and forming the upper trench having a vertical cross-section in the active region of the semiconductor substrate by an etch process using the screen oxide layer pattern and the amorphous carbon layer pattern as an etch mask.

The silicon nitride barrier layer preferably is formed by atomic layer deposition (ALD), preferably at a temperature of 400° C. to 500° C.

Forming the silicon nitride barrier layer preferably comprises absorbing silicon (Si) onto an exposed face of the upper trench by supplying a silicon source onto the semiconductor substrate formed with the upper trench; removing non-absorbed silicon by injecting a purge gas onto the semiconductor substrate; forming a monoatomic layer of the silicon nitride barrier layer with bonding of the silicon absorbed onto the exposed face of the upper trench and nitrogen (N) in an ammonia gas by supplying an ammonia (NH₃) gas with turning on of plasma; removing unreacted substances by injecting a purge gas onto the semiconductor substrate; and forming the silicon nitride barrier layer by repeating the absorption of the silicon through removal of the unreacted substances.

The silicon source preferably comprises a dichlorosilane (SiCl₂H₂) gas.

The silicon nitride barrier layer preferably is deposited to a thickness of 20 Å to 50 Å by implementing the absorption of the silicon through the discharge of the unreacted substances at least 50 cycles.

The silicon nitride barrier layer preferably has an etch selectivity with respect to the oxide layer of the isolation layer to prevent the isolation layer from being excessively etched toward side faces and widened.

The bulb-type lower trench preferably is formed by an isotropic etch process.

Preferably he bulb-type lower trench is formed by supplying an etch source comprising a trifluoromethane (CHF₃) gas or a hydrogen bromide (HBr) gas.

The bulb-type lower trench preferably is formed by etching to a depth of 200 Å to 400 Å and a bulb width of 35 Å to 45 Å, respectively, from the bottom face of the upper trench.

The bulb recess trench preferably comprises the upper trench with a first width and the lower trench with a second width relatively wider than that of the upper trench.

In one embodiment, a method for fabricating a semiconductor device having a recess channel comprises forming an isolation layer that delimits an active region over a semiconductor substrate; forming, over the semiconductor substrate, an amorphous carbon-based hard mask layer pattern that exposes a region to be formed with a bulb recess trench; forming, on a side wall of the upper trench, a silicon nitride barrier layer that prevents lifting of the amorphous carbon-based hard mask layer pattern and exposes a bottom face of the upper trench; forming a lower trench of a bulb type by etching the exposed bottom face of the upper trench using the silicon nitride barrier layer as an etch mask, to form the bulb recess trench comprising the upper trench and the lower trench; forming a fin-structured bottom protrusion part comprising an upper face and a side face by etching the isolation layer so that the isolation layer has a surface lower than the bottom face of the lower trench; and forming a gate stack overlapped with the bulb recess trench and the bottom protrusion part.

### BRIEF DESCRIPTION OF THE DRAWINGS

FIGS. 1A through 10 illustrate a method for fabricating a semiconductor device having a recess channel in accordance with an embodiment of the invention.

### DESCRIPTION OF SPECIFIC EMBODIMENTS

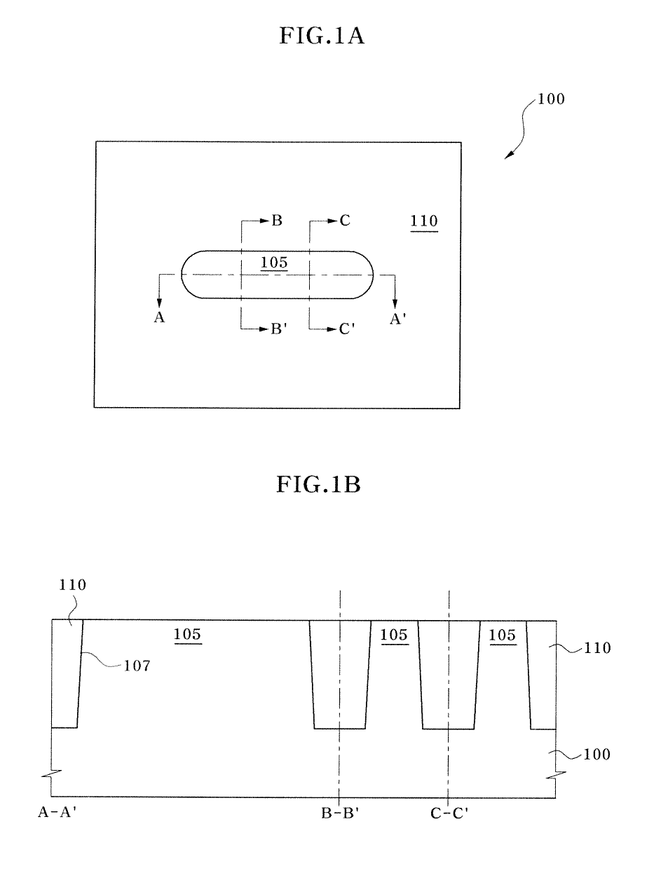

FIGS. 1A through 10 illustrate a method for fabricating a semiconductor device having a recess channel in accordance with an embodiment of the invention.

In FIGS. 1A and 1B, an isolation layer 110 delimits an active region 105 in the semiconductor substrate 100. FIG. 1B illustrates cross-sectional views taken along lines A-A′, B-B′, and C-C′ in FIG. 1A. Specifically, a pad oxide layer pattern (not shown) and a pad nitride layer pattern (not shown) that form an isolation region are formed over the semiconductor substrate 100. The pad oxide layer pattern preferably is formed to a thickness of 50 Å to 150 Å, and the pad nitride layer pattern preferably is formed to a thickness of 500 Å to 1000 Å.

Next, the exposed portion of the semiconductor substrate 100 is etched using the pad oxide layer pattern and the pad nitride layer pattern as an etch mask to form an isolation trench 107, preferably with a depth of 2000 Å to 3000 Å.

Next, the isolation trench 107 is filled with an insulation layer and a planarization process is performed on the insulation layer to form the isolation layer 110 that delimits the active region 105 and the isolation region. Here, the insulation layer preferably is formed by a high density plasma (HDP) process. The planarization process preferably is implemented by a chemical mechanical polishing (CMP) process. Next, the pad oxide layer pattern and the pad nitride layer pattern are removed, preferably by a strip process.

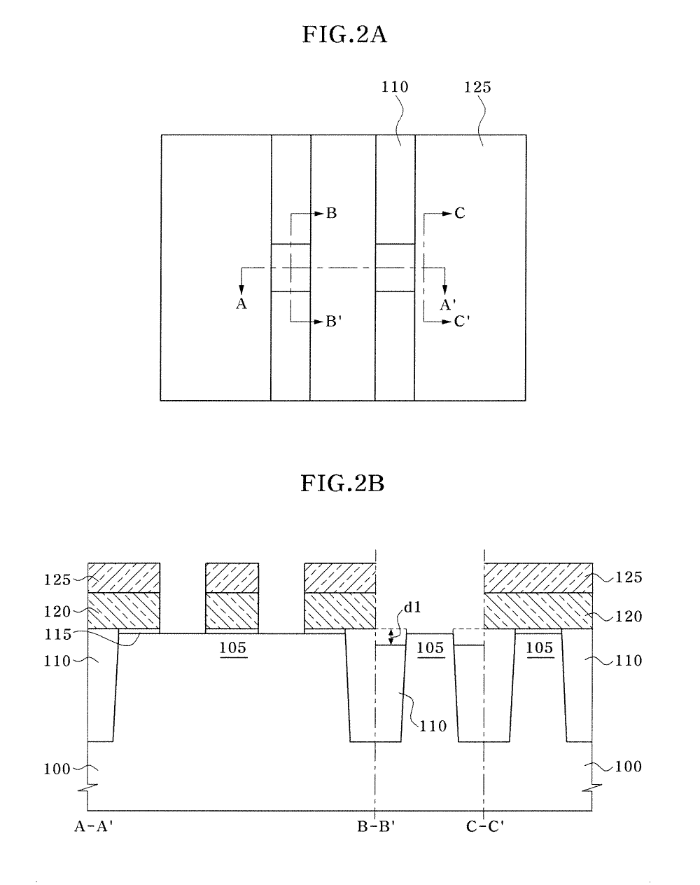

Referring to FIGS. 2A and 2B, a screen oxide layer 115 and a hard mask layer 120 that selectively expose the active region 105 of the semiconductor substrate 100 are formed. Specifically, the screen oxide layer 115 is formed over the active region 105 of the semiconductor substrate 100. The screen oxide layer controls damage caused over the semiconductor substrate 100 in an ion implantation process, and preferably is formed to a thickness of 50 Å to 60 Å. Next, the hard mask layer 120 is formed over the screen oxide layer 115. This hard mask layer functions later as an etch mask in an etch process for forming a recess trench. A resist layer is successively coated over the hard mask layer and a photolithography process including exposure and development processes is performed to form a resist layer pattern 125. The resist layer pattern 125 preferably is formed in a shape of a stripe extending across the active region 105 of the semiconductor substrate 100 in the direction of a minor axis of the active region.

Next, the exposed portion of the hard mask layer is etched using the resist layer pattern 125 as an etch mask to form a hard mask layer pattern 120. The exposed portion of the screen oxide layer is successively etched using the hard mask layer pattern 120 to form a screen oxide layer pattern 115 that exposes some portion of the surface of the semiconductor substrate 100. In this case, referring to a cross-sectional view taken along the minor axis of the active region 105, i.e. a line B-B′ in FIG. 2B, the isolation layer 110 is also etched in the etch process performed for forming the hard mask layer pattern 125. Consequently, the isolation layer 110 is etched by a first depth (d1) from the exposed surface to expose some upper portion of the active region 105 by the etched depth. Here, referring to a cross-sectional view taken along a line C-C′ in FIG. 2B, the portion of the isolation layer 110 covered by the resist layer pattern 125 is left in an unetched state. Next, the resist layer pattern 125 is removed, preferably by a strip process.

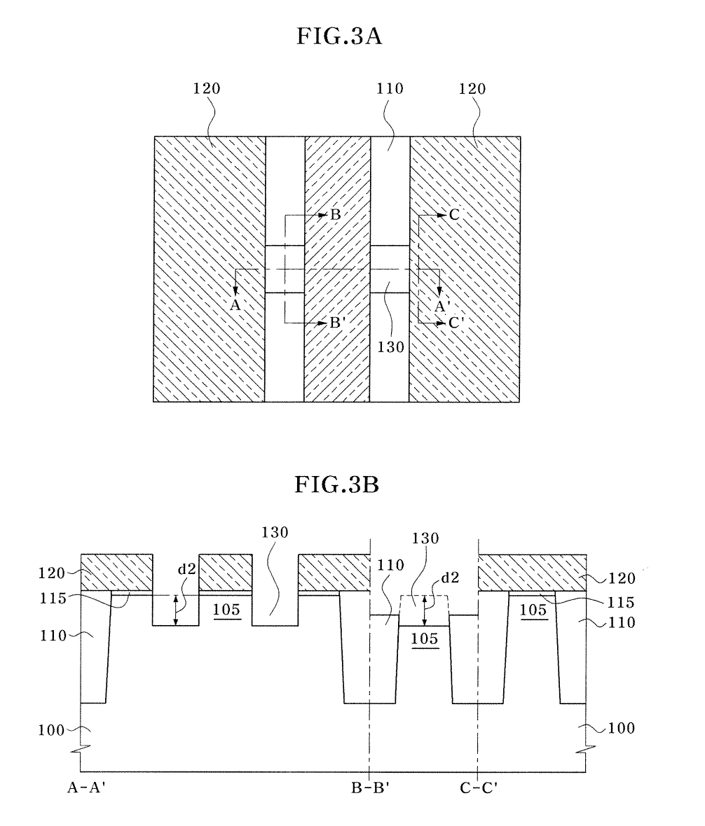

Referring to FIGS. 3A and 3B, an upper trench 130 is formed in the active region 105 of the semiconductor substrate 100 by an etch process using the hard mask layer pattern 120 and the screen oxide layer pattern 115 as an etch mask. The upper trench 130 is formed to a second depth (d2), e.g. 800 Å to 1000 Å from the surface of the semiconductor substrate 100. This upper trench 130 is formed having a vertical cross-sectional shape. In this case, referring to a cross-sectional view taken along a line B-B′ in FIG. 3B, i.e. the minor axis of the active region 105, the active region of which some upper portion is exposed is also etched by the second depth (d2) of the upper trench 130 from the exposed surface thereof during the etching process of forming the upper trench 130. Consequently, a height difference between the isolation layer 110 and the active region 105 can be reduced.

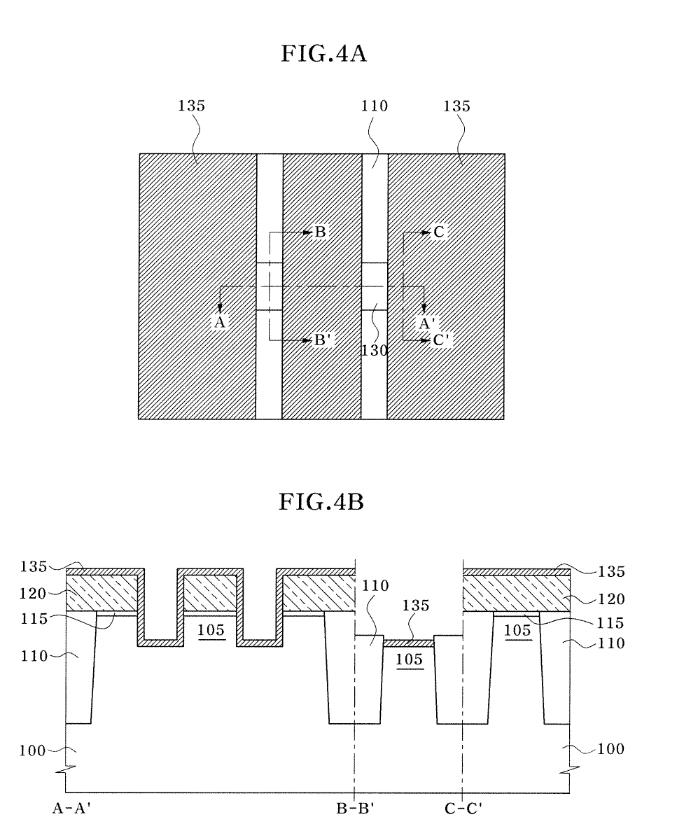

Referring to FIGS. 4A and 4B, a silicon nitride layer 135 is deposited as an etch barrier layer over the hard mask layer pattern 120 and the exposed portions of the upper trench 130. When the barrier layer comprises an oxide layer, the isolation layer 110 is etched together in an etch process for forming a lower trench to be formed later, which can cause a defect wherein the isolation layer 110 is widened in a direction of the minor axis of the active region 105. Accordingly, the silicon nitride layer 135 is formed as the etch barrier layer.

In the present embodiment, the silicon nitride layer 135 preferably is formed by an atomic layer deposition (ALD) process, preferably at a low temperature of 400° C. to 500° C. To this end, the semiconductor substrate 100 is first loaded in deposition equipment, preferably batch-type plasma equipment in which a plurality of wafers are mounted. Next, a nitrifying deposition source is supplied into the deposition equipment. The nitrifying deposition source preferably comprises a dichlorosilane (SiCl₂H₂) gas and an ammonia (NH₃) gas. Specifically, the dichlorosilane (SiCl₂H₂) gas is supplied into the plasma equipment with application of a bias. Then, silicon is absorbed onto a to-be-deposited face to be formed with the silicon nitride layer 135. Next, a purge gas is injected into the deposition equipment to discharge non-absorbed silicon. The ammonia (NH₃) gas is subsequently supplied into the deposition equipment with the plasma turned on. Then, the silicon absorbed onto the hard mask layer pattern 120 and the exposed face of the upper trench 130 and nitrogen in the ammonia (NH₃) gas are bonded to form a monoatomic layer of silicon nitride (SiₓN_{y}). Next, a purge gas is injected into the deposition equipment to exhaust the inside of the deposition equipment. This monoatomic layer of the silicon nitride (SiₓN_{y}) layer preferably is deposited at a deposition speed of 0.8 Å per cycle. In the present embodiment, the silicon nitride layer 135 preferably is deposited to a thickness of 20 Å to 50 Å by performing the ALD at least 50 cycles.

The silicon nitride layer 135 deposited by the ALD at a low temperature of 400° C. to 500° C. as described above functions as a barrier to prevent a side wall of the upper trench 130 from being etched in the etch process to be performed later for forming a bulb-type lower trench. Also, since the silicon nitride layer 135 has an etch selectivity with respect to the oxide layer of the isolation layer 110 in the etch process to be performed for forming the bulb type lower trench, the silicon nitride layer 135 functions as a barrier layer for preventing the isolation layer from being excessively etched toward side faces and thus widened. Also, when the hard mask layer pattern 120 is formed of an amorphous carbon layer, the structure prevents a lifting phenomenon wherein the amorphous carbon layer is lifted in the etch process to be performed for forming the bulb type lower trench.

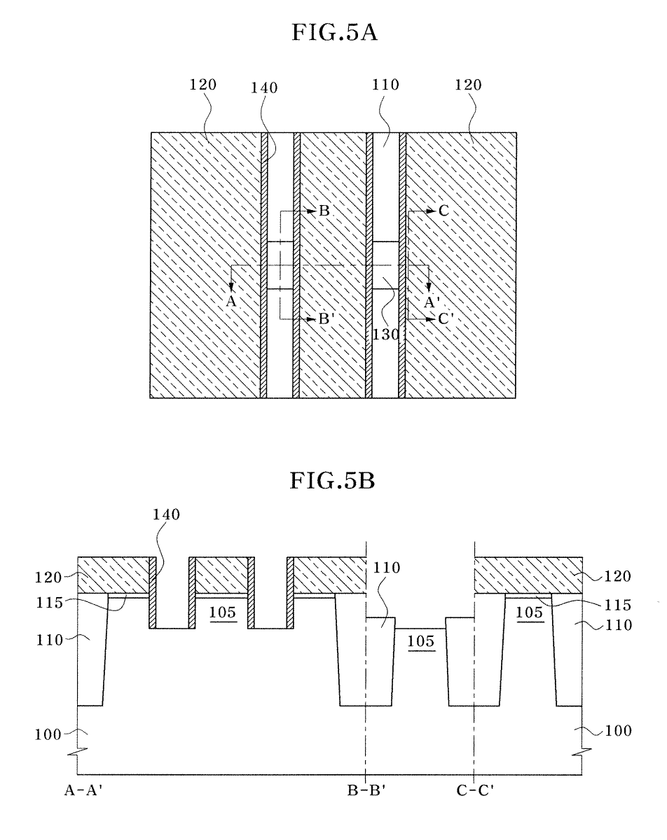

Referring to FIGS. 5A and 5B, portions of the silicon nitride layer (135, refer to line B-B′ in FIG. 4B) corresponding to the upper portion of the hard mask layer 120 and the bottom face of the upper trench 130 are etched to form an etch barrier layer 140 on the side wall of the upper trench 130. The etch barrier layer 140 can be formed by etching the silicon nitride layer 135 in a vertical direction. Then, silicon in the bottom face of the upper trench 130 is exposed. This etch barrier layer 140 functions as a barrier to prevent the side face of the upper trench 130 from being etched in the etch process for forming the bulb type lower trench. In this case, referring to a cross-sectional view taken along a line B-B′ in FIG. 4B, i.e. the minor axis of the active region 105, the silicon nitride layer (135, refer to B-B′ in FIG. 5B) deposited over the isolation layer 110 is also removed in the vertical etch process and surfaces of the isolation layer 110 and the active region 105 are exposed.

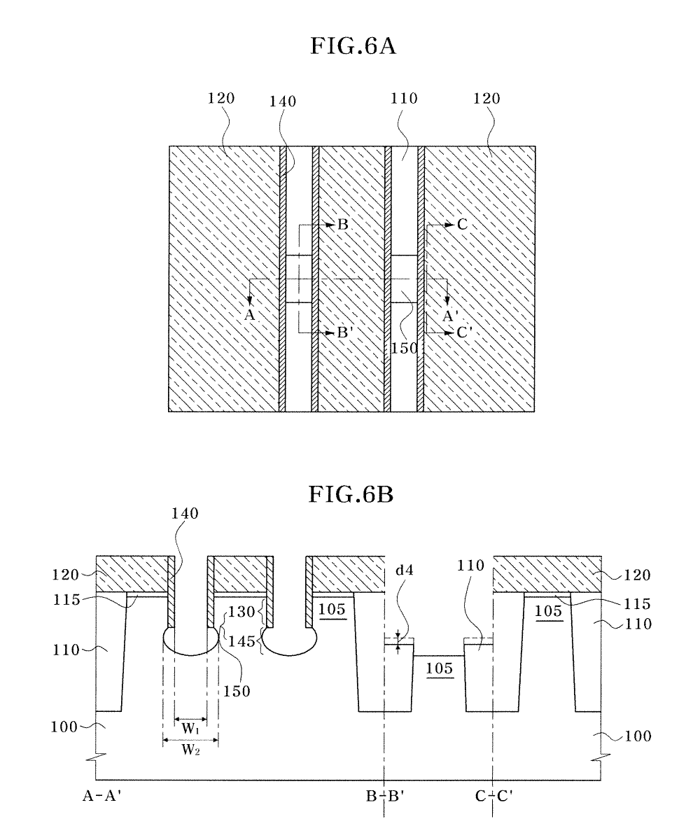

Referring to FIGS. 6A and 6B, an etch process using the etch barrier layer 140 as an etch mask is performed to form a bulb-type lower trench 145 below the upper trench 130. Here, the bulb-type lower trench 145 is formed by an etch from the bottom face of the upper trench (130, refer to FIG. 5B). The etch process of forming the bulb-type lower trench 145 preferably is implemented in an isotropic etch process, in which the etch is performed at the same speed in all directions and thus the shape after the etch is a curved face. The isotropic etch is preferably implemented by supplying an etch source comprising a trifluoromethane (CHF₃) gas or a hydrogen bromide (HBr) gas. Here, the bulb-type lower trench 145 preferably is etched by a depth of 200 Å to 400 Å and a bulb width of 35 Å to 45 Å from the bottom face of the upper trench 130. In this case, it is preferable to form the bulb width to 35 Å to 45 Å, which is relatively narrower than the conventional bulb width of 60 Å to 70 Å.

Accordingly, a bulb recess trench 150 having the upper trench 130 with a first width (w1) and the lower trench 145 with a second width (w2) relatively wider than that of the upper trench 130 is formed in the semiconductor substrate 100. At this time, the etch barrier layer 140 prevents the side face of the upper trench from being etched during the isotropic etch and resulting damage of the semiconductor substrate 100. Also, the etch barrier layer 140 has an etch selectivity with respect to the silicon of the semiconductor substrate 100 and the oxide layer of the isolation layer 110 and thus prevents the isolation layer 110 from being excessively etched toward the side directions and widened, thereby expanding the isolation region. In this case, referring to a cross-sectional view taken along a line B-B′ in FIG. 6B, i.e. the minor axis of the active region, the isolation layer 110 exposed to the etch source is also etched to a fourth depth (d4) from the exposed surface during the etch process for forming the bulb type lower trench 145. At this time, referring to a cross-sectional view taken along a line C-C′ in FIG. 6B, the portion covered by the hard mask layer pattern 120 is not influenced by the etch source and thus is not etched.

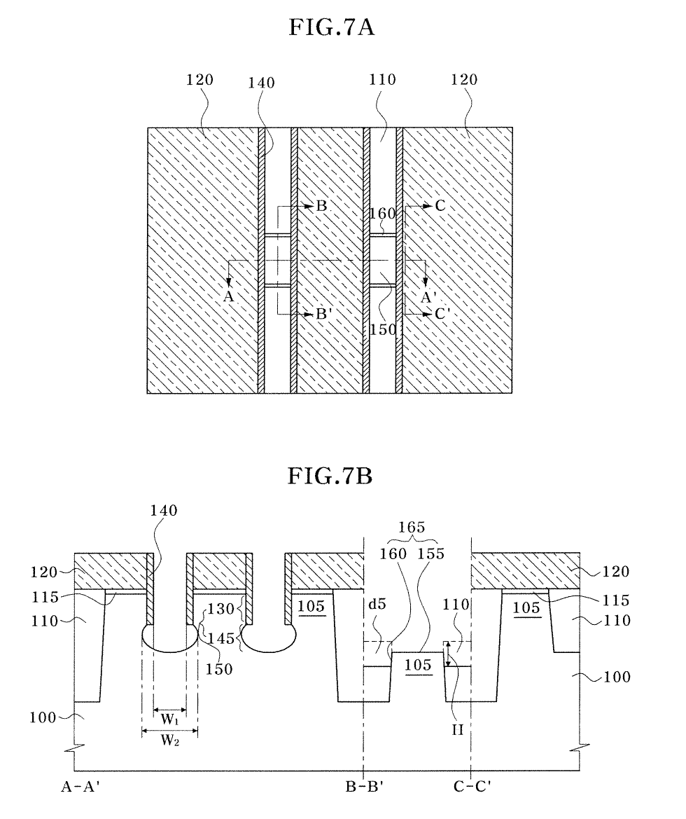

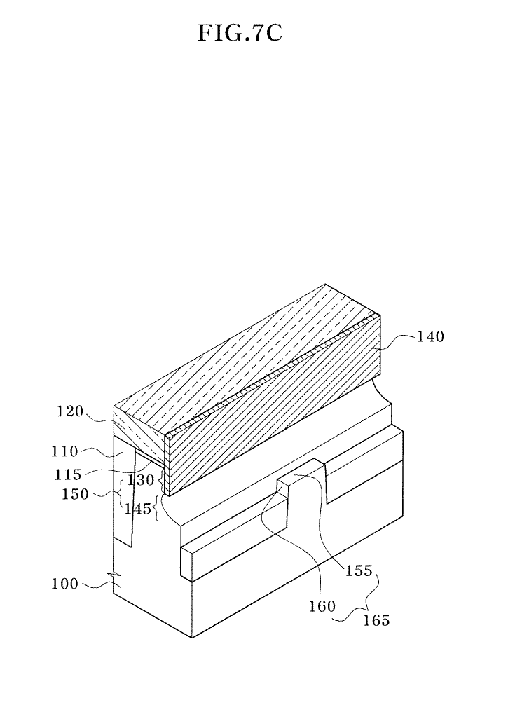

Referring to FIGS. 7A to 7C, the exposed surface of the isolation layer 110 is etched to a fifth depth (d5) to form a bottom protrusion part 165 with a fin structure having an upper face 155 and side faces 160. The bottom protrusion part 165 preferably is formed having a height (H) of 300 Å to 600 Å.

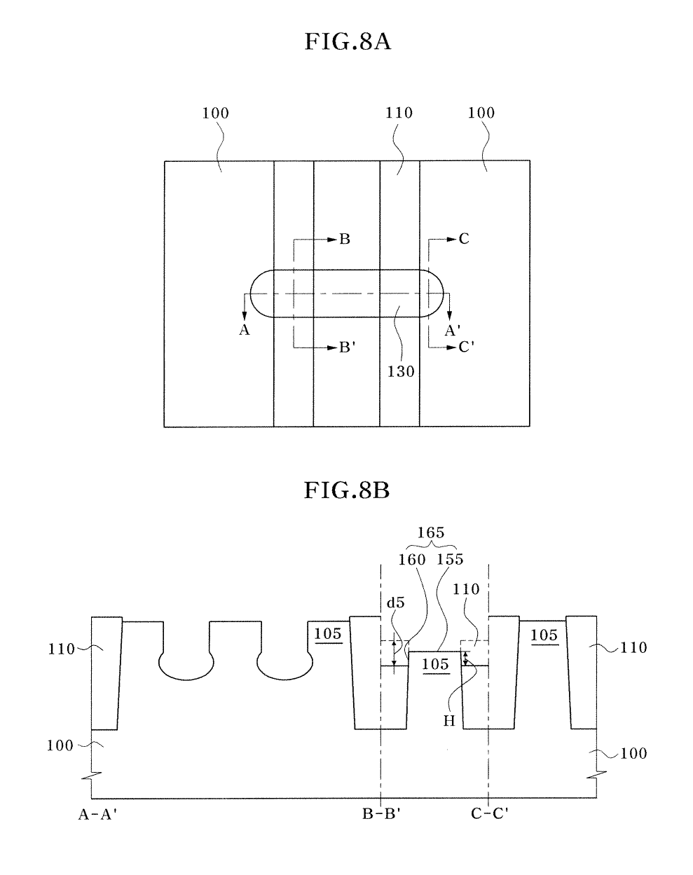

Referring to FIGS. 8A and 8B, the hard mask layer pattern 120 and the screen oxide layer pattern 115 are removed.

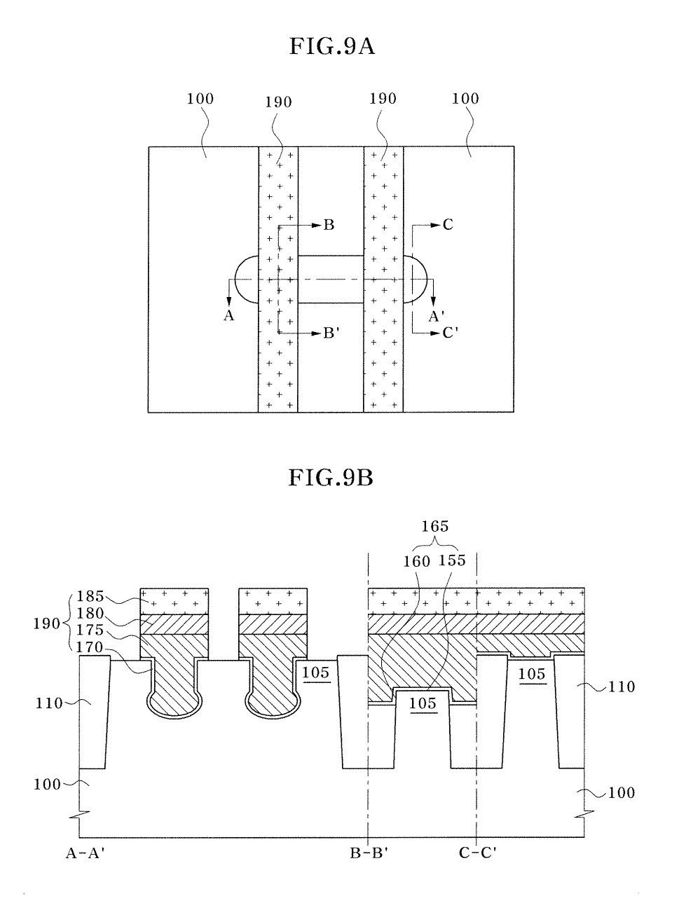

Referring to FIGS. 9A and 9B, a gate stack 190 overlapped with the bulb recess trench 150 is formed. Specifically, an oxide layer or a gate insulation layer preferably is formed to a thickness of 30 Å to 50 Å over the semiconductor substrate 100, and a doped polysilicon layer or a conductive layer is formed, preferably to a thickness of 400 Å to 700 Å. Next, a tungsten silicide (WSiₓ) layer or a metal layer is formed, preferably to a thickness of 1000 Å to 1500 Å over the conductive layer, and a hard mask layer is formed, preferably to a thickness of 2000 Å to 2500 Å. Next, a selective etch process for gate patterning is performed to form a gate stack 190. The gate stack 190 includes a gate insulation layer pattern 170, a conductive layer pattern 175, a metal layer pattern 180, and a hard mask layer pattern 185.

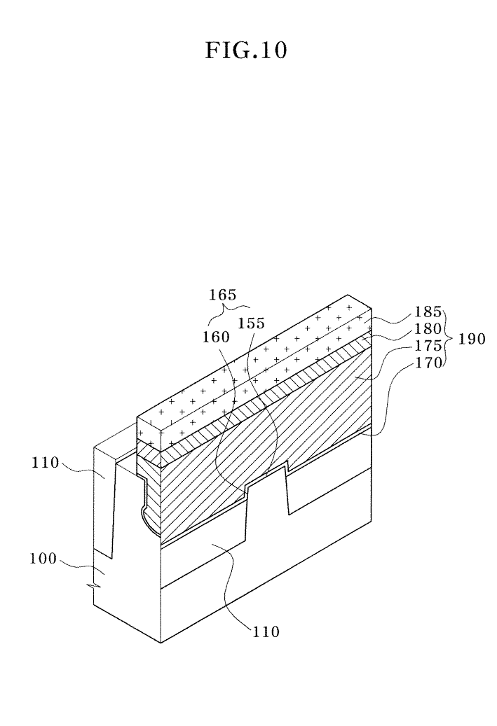

FIG. 10 is a perspective view illustrating a cross-section of a semiconductor device in accordance with an embodiment of the invention. Referring to FIG. 10, the isolation layer 110 is etched by a predetermined depth to a point where the side wall 160 of the fin-structured bottom protrusion part 165. Next, the gate insulation layer pattern 170 extends along the isolation layer 110 and the exposed face of the fin-structured bottom protrusion part 165. The conductive layer pattern 175 extends along both side walls 160 and the upper face 155 of the fin-structured bottom protrusion part 165, filling all the bulb recess trenches 150.

As is apparent from the above description, in accordance with a method for fabricating a semiconductor device having a recess channel of the invention, the transistor is formed including the bulb recess trench and a fin structured bottom protrusion part. Therefore, it is possible to ensure a channel length to improve the refresh property, and it is also possible to improve a margin property of the cell threshold voltage by the fin structured bottom protrusion part.

While the invention has been described with respect to the specific embodiments, various changes and modifications may be made without departing from the spirit and scope of the invention as defined in the following claims.

What is claimed is:

1. A method for fabricating a semiconductor device having a recess channel, comprising:
forming an isolation layer that delimits an active region over a semiconductor substrate;
exposing a region to be formed with a bulb recess trench over the semiconductor substrate;
forming an upper trench by etching the exposed region of the semiconductor substrate;
forming, on a side wall of the upper trench, a silicon nitride barrier layer that exposes a bottom face of the upper trench but blocks the side wall of the upper trench;
forming a lower trench of a bulb type by etching the exposed bottom face of the upper trench using the silicon nitride barrier layer as an etch mask, to form a bulb recess trench including the upper trench and the lower trench;
forming a fin-structured bottom protrusion part including an upper face and a side face by etching the isolation layer so that the isolation layer has a surface lower than the bottom face of the lower trench; and
forming a gate stack overlapped with the bulb recess trench and the bottom protrusion part.

2. The method of claim 1, wherein forming the upper trench comprises:
blocking the exposed region of the semiconductor substrate except for the region to be formed with the bulb recess trench in the active region by forming a screen oxide layer pattern and an amorphous carbon layer pattern over the semiconductor substrate; and
forming the upper trench having a vertical cross-section in the active region of the semiconductor substrate by an etch process using the screen oxide layer pattern and the amorphous carbon layer pattern as an etch mask.

3. The method of claim 1, comprising forming the silicon nitride barrier layer by atomic layer deposition (ALD) at a temperature of 400° C. to 500° C.

4. The method of claim 1, comprising forming the silicon nitride barrier layer by:
absorbing silicon (Si) onto an exposed face of the upper trench by supplying a silicon source onto the semiconductor substrate formed with the upper trench;
removing non-absorbed silicon by injecting a purge gas onto the semiconductor substrate;
forming a monoatomic layer of the silicon nitride layer with bonding of the silicon absorbed onto the exposed face of the upper trench and nitrogen (N) in an ammonia gas by supplying an ammonia (NH₃) gas with turning on of plasma;
removing unreacted substances by injecting a purge gas onto the semiconductor substrate; and
forming the silicon nitride barrier layer by repeating the absorption of the silicon through removal of the unreacted substances.

5. The method of claim 4, wherein the silicon source comprises a dichlorosilane (SiCl₂H₂) gas.

6. The method of claim 4, comprising depositing the silicon nitride barrier layer to a thickness of 20 Å to 50 Å by implementing the absorption of the silicon through the discharge of the unreacted substances at least 50 cycles.

7. The method of claim 1, wherein the silicon nitride barrier layer has an etch selectivity with respect to the oxide layer of the isolation layer to prevent the isolation layer from being excessively etched toward side faces and widened.

8. The method of claim 1, comprising forming the bulb-type lower trench by an isotropic etch.

9. The method of claim 1, comprising forming the bulb-type lower trench by supplying an etch source including a trifluoromethane (CHF₃) gas or a hydrogen bromide (HBr) gas.

10. The method of claim 1, comprising forming the bulb-type lower trench etched by a depth of 200 Å to 400 Å and a bulb width of 35 Å to 45 Å, respectively, from the bottom face of the upper trench.

11. The method of claim 1, comprising forming the bulb recess trench including the upper trench with a first width and the lower trench with a second width relatively wider than that of the upper trench.

12. A method for fabricating a semiconductor device having a recess channel, comprising:
forming an isolation layer that delimits an active region over a semiconductor substrate;
forming, over the semiconductor substrate, an amorphous carbon-based hard mask layer pattern, that exposes a region to be formed with a bulb recess trench;
forming, on a side wall of the upper trench, a silicon nitride barrier layer that prevents lifting of the amorphous carbon-based hard mask layer pattern and exposes a bottom face of the upper trench;
forming a lower trench of a bulb type by etching the exposed bottom face of the upper trench using the silicon nitride barrier layer as an etch mask, to form the bulb recess trench including the upper trench and the lower trench;
forming a fin-structured bottom protrusion part including an upper face and a side face by etching the isolation layer so that the isolation layer has a surface lower than the bottom face of the lower trench; and
forming a gate stack overlapped with the bulb recess trench and the bottom protrusion part.

13. The method of claim 12, comprising forming the silicon nitride barrier layer by atomic layer deposition (ALD) at a temperature of 400° C. to 500° C.

14. The method of claim 12, wherein forming the silicon nitride barrier layer comprises:
absorbing silicon (Si) onto an exposed face of the upper trench by supplying a silicon source onto the semiconductor substrate formed with the upper trench;
removing non-absorbed silicon by injecting a purge gas onto the semiconductor substrate;
forming a monoatomic layer of the silicon nitride barrier layer with bonding of the silicon absorbed onto the exposed face of the upper trench and nitrogen (N) in an ammonia gas by supplying an ammonia (NH₃) gas with turning on of plasma;
removing unreacted substances by injecting a purge gas onto the semiconductor substrate; and
forming the silicon nitride barrier layer by repeating the absorption of the silicon through removal of the unreacted substances.

15. The method of claim 14, comprising depositing the silicon nitride barrier layer to a thickness of 20 Å to 50 Å by implementing the absorption of the silicon through the discharge of the unreacted substances at least 50 cycles.

16. The method of claim 12, wherein the silicon nitride barrier layer has an etch selectivity with respect to the oxide layer of the isolation layer to prevent the isolation layer from being excessively etched toward side faces and widened.
